(19) United States
(12) Patent Application Publication
(10) Pub. No.: US 2008/0104487 A1
(43) Pub. Date: May 1, 2008

(54) Error detection apparatus and error detection method

(75) Inventor: Kazuki Usui, Kasugai (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/907,125

(22) Filed: Oct. 9, 2007

(30) Foreign Application Priority Data
Oct. 31, 2006 (JP) 2006-295710

(51) Int. Cl. H03M 13/00

(52) U.S. Cl. 714/785

(57) ABSTRACT

When error bit position information EbP sequentially selected from a register 51 is an error bit position, such a syndrome that an LSB of an error byte position is an error bit position is output from a syndrome storage unit 52 to an adder 54 and added and stored in a register 55. Further, a one-shift computing unit (β¹) 57 performs computations equivalent to a one-shift operation by an LFSR. The adder 54 sends to the register 55, if input, a sum of the syndrome and an output of the one-shift computing unit (β¹) 57, otherwise, the output of the one-shift computing unit (β¹) 57. By repeating this operation for as many times as the number of bits as counted from the error bit position to the LSB in the error byte position, a compensation syndrome SC is obtained. Accordingly, shortened processing time and simplified processing circuitry can be attained.

### CROSS-REFERENCE TO RELATED APPLICATIONS

This application is based upon and claims the benefit of priority from the prior Japanese Patent Application No. 2006-295710 filed on Oct. 31, 2006, the entire contents of which are incorporated herein by reference.

### BACKGROUND

1. Field

The present embodiment relates to detection of a code error contained in digital data and, more specifically to, error detection by use of a cyclic code.

2. Description of the Related Art

Conventionally, in addition to error correction processing performed on transmitted digital data, a cyclic code such as a CRC code has been used in error detection to decide whether error correction has been performed correctly. This is performed by adding an error detection code (hereinafter abbreviated as an EDC) to original data. In this case, to reduce the number of times of an access operation such as a data write or read operation which is performed to a memory device such as a DRAM each time an error is corrected or detected, in some cases, at a stage preceding the error correction, the error is detected so that a result of the error detection may be compensated by using a bit position of error data obtained through the error correction.

In description of a data decoding processing apparatus of Japanese Unexamined Patent Publication No. 2000-165259, a DVD-ROM data reproduction apparatus is disclosed. If an error correction unit detects error “1” at a bitwise i'th position in a code sequence, whether error detection has been performed on an error data row is computed. First, data “0” is circulated through an EDC circuit (linear feedback shift register) until data “1” is encountered without a change in value. By inputting data “1” and then shifting the EDC circuit (linear feedback shift register) for i number of times, a compensation value is obtained. If there are a plurality of errors contained in the data, compensation values for them are EXOR-ed.

According to a CRC check result compensation method disclosed in Japanese Unexamined Patent Publication No. 63(1988)-281277, in a case where an error is corrected by using a result of syndrome computations through ECC, corrected values are tabulated on the basis of an error position and a correction pattern which are derived from the computation result. The compensation values are computed using the corrected error position and pattern by means of a microprogram.

### SUMMARY

It is an aspect of the embodiments discussed herein to provide an error detection apparatus including a first linear feedback shift register creating a first syndrome by using a cyclic code before error correction for received data in which a plurality of data units are arrayed each of which is constituted of a bit row constituted of a predetermined number of bits, a storage unit storing beforehand, for each of the data units, a second syndrome which is computed in a case where an error exists at a specified bit position in the bit row, a computing unit reading from the storage unit, as an initial code, the second syndrome in the data unit that is pinpointed by the error correction information as containing the error and outputs a result of computations equivalent to a shift operation being performed by a linear feedback shift register as many times as a bit difference as counted from an error bit position to the specified bit position in the data unit, a first adder unit that the computation results output from the computing unit for each of the error bit positions is EXOR-ed with and to be output as a third syndrome, and a second adder unit that the first syndrome is EXOR-ed with the third syndrome.

### BRIEF DESCRIPTION OF THE DRAWINGS

FIG. 1 shows a data format for one DVD sector;

FIG. 2 is a circuit diagram of a linear feedback shift register (LFSR);

FIG. 3 is a circuit block diagram of a data reception system equipped with an error detection circuit of an embodiment;

FIG. 4 is a circuit diagram showing an error detection circuit of a first embodiment;

FIG. 5 shows a constitution of a one-shift computing unit (β1);

FIG. 6 shows an example of error information and a principle for deriving a compensation syndrome in the first embodiment;

FIG. 7 is a flowchart showing a processing flow in the first embodiment;

FIG. 8 is a circuit diagram showing an error detection circuit of a second embodiment;

FIG. 9 shows a constitution of a shift computing unit (βN);

FIG. 10 is a circuit diagram showing an error detection circuit of a third embodiment;

FIG. 11 shows an example of the error information and a principle for deriving a compensation syndrome in the third embodiment;

FIG. 12 is a flowchart showing a processing flow in the third embodiment; and

FIG. 13 is a circuit diagram showing an error detection circuit of a fourth embodiment.

### DESCRIPTION OF THE PREFERRED EMBODIMENTS

The aforementioned related art, obtaining of a compensation value for an error detection result by use of the above-described background technology may possibly require an extremely long computation time and a large circuit scale, thus causing s problem.

Specifically, in the data decoding processing apparatus disclosed in Japanese Unexamined Patent Publication No. 2000-165259, all of bit rows of a code sequence must be input into the EDC circuit (linear feedback shift register) and circulated through it regardless of an error 1” bit position in the code sequence. Until a compensation value is obtained, it is necessary to use a computation time for the number of cycles equal to the number of bits of at least the bit rows of the code sequence regardless of the positions of the bits to be corrected and the number of the bits. For example, in a DVD-ROM, a code sequence has 16512 bits, so that a computation time is required for 16512 cycles. A vast computation time may possibly be required.

Further, according to the CRC check result correction method disclosed in Japanese Unexamined Patent Publication No. 63(1988)-281277, it is necessary to provide a compensation value for each of bit positions of error bits to be corrected using an ECC. Depending on the number of bits of each of bit rows that constitute digital data subject to error correction and error detection, such a case may be considered that the number of combinations of compensation values to be provided may be enormous. A table that contains all of the compensation values may possibly have a vast amount of data, thus resulting in an increase in size of a storage region that stores the table values and scale of a circuit that controls the storage region.

In view of the aforementioned related art, and it is an object of the embodiment to provide an error detecting apparatus and method that can efficiently compute a compensation value based on an error bit position obtained by error correction processing in the case of error correction and error detection are performed by use of a cyclic code, thereby shortening a processing time required in the correction and simplifying a circuit required in error detection processing.

The above and further novel features of the invention will more fully appear from the following detailed description when the same is read in connection with the accompanying drawings. It is to be expressly understood, however, that the drawings are for the purpose of illustration only and are not intended as a definition of the limits of the invention.

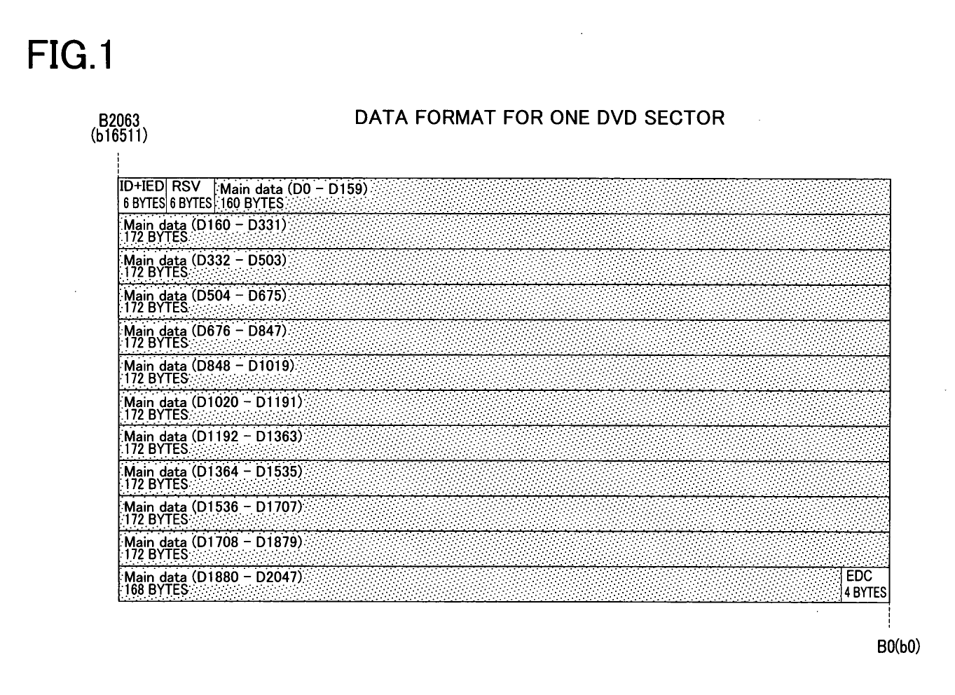

The following will describe in detail specific embodiments of an error detection apparatus and an error detection method with drawings of FIGS. 1-13.

An error detection apparatus and method will, in demodulation of received data provided with an EDC indicative of properties of a cyclic code, be EXOR-ed an error detection result computed at a stage preceding error correction with an error detection result computed with respect to error correction information as a compensation value, thereby performing error detection on the received data. It is to be noted that the error correction information refers to information that indicates an error position in received data. If such a constitution is considered that received data may be delimited into data units each of which has one byte, the error correction information is constituted of a byte position in the received data and an error bit position in this byte position.

The error detection apparatus and method can be applied effectively as far as a cyclic code is used in error detection. Examples of the cyclic code may include a CRC code. The first through fourth embodiments will be described below with reference to a case where a CRC code is used as a cyclic code.

FIG. 1 shows a data format for one DVD sector as an example in a case where a CRC code is used. Four-byte ID data is combined with two-byte IED data which is used in error detection for the ID data, to arrange a total of six bytes of ID-associated data. The ID-associated data is followed by six-byte RSV data. The total 12 bytes of data constitutes control data. This is followed by 2048-byte user data as main data. At the end, a four-byte EDC code for all of the data pieces is arranged. The 2064 bytes make up one sector. It is to be noted that a last bit of the four-byte EDC code is the LSB in each sector, that is, a bit 0 (b0) in byte 0 (B0), and a first bit of the four-byte ID data is the MSB in each sector, that is, bit 16511 (b16511) in byte 2063 (B2063). An error detection apparatus and method of the first through fourth embodiments will be described below with reference to an exemplified case where error detection is performed on one sector (which has 2064 bytes) of a DVD.

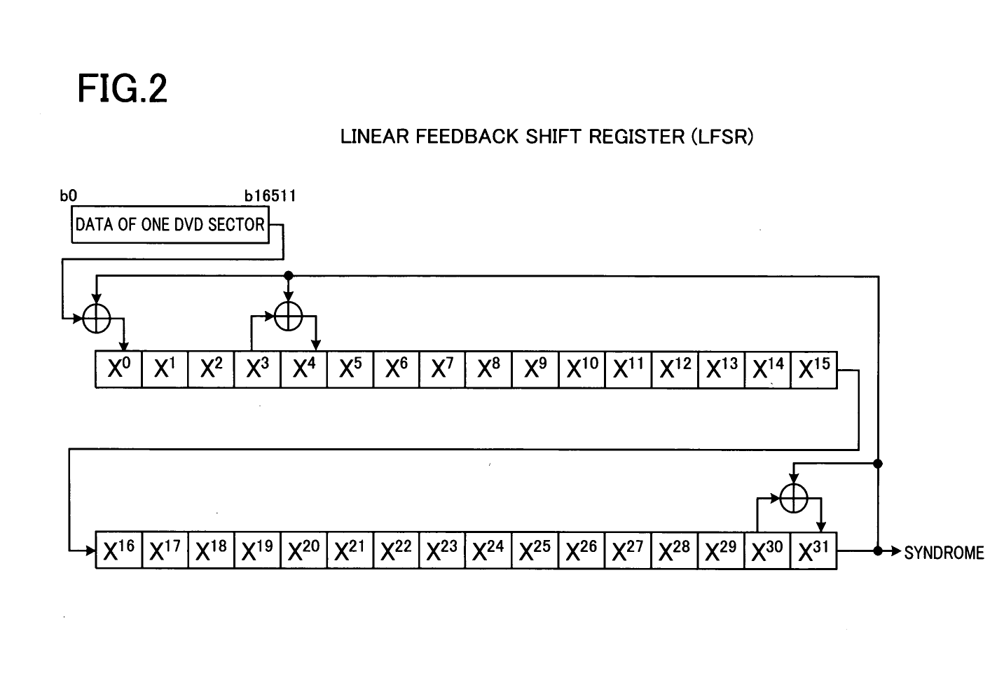

A linear feedback shift register (hereinafter abbreviated as LFSR) shown in FIG. 2 provides a bit row having 32 bits of X⁰ through X³¹ as a result of error detection performed on one-sector data of the DVD. This bit row is a syndrome or a result for a parity code.

Sector data of the DVD is sequentially input starting with bit 16511 (b16511), which is the MSB. The input bit data is EXOR-ed with bit data of bit position (X³¹) and input to bit position (X⁰). In the LFSR, bit data is shifted sequentially toward a higher-order bit position. Meanwhile, bit position (X³) and bit position (X³¹) are EXOR-ed and input to bit position (X⁴), and bit position (X³⁰) and bit position (X³¹) are EXOR-ed and input to bit position (X³¹). At a moment when bit 0 (b0), which is the LSB of each of the DVD sectors, is EXOR-ed with bit position (X³¹) and input to bit position (X⁰), computations of a syndrome are completed. If bit data of a bit row of X⁰ through X³¹ have a predetermined value at the moment, it means that the one-sector data has no error. The bit data of the bit row of these X⁰ through X³¹ is the syndrome. Further, if the bit data of the bit row of X⁰ through X³¹ has value “0”, such a setting may be considered as to assume that the one-sector data has no error. This is error detection. In the following description, bit data of a bit row of X⁰ through X³¹ is supposed to be a syndrome. Further, creation of parity involves computations similar to those for a syndrome, so that the present specification can be applied to the creation of parity, needless to say.

Now, 0 is set to bit positions X¹ through X³¹ of the LFSR and 1 is set to bit position X⁰. This state is defined as β⁰. The state of the LFSR when it has shifted by one clock pulse (×β¹) from β⁰ with 0 being input is defined as β¹, and the state of the LFSR when it has shifted by m number of clock pulses (×β^{m}) from βⁿ with 0 being input is defined as β^{n+m}.

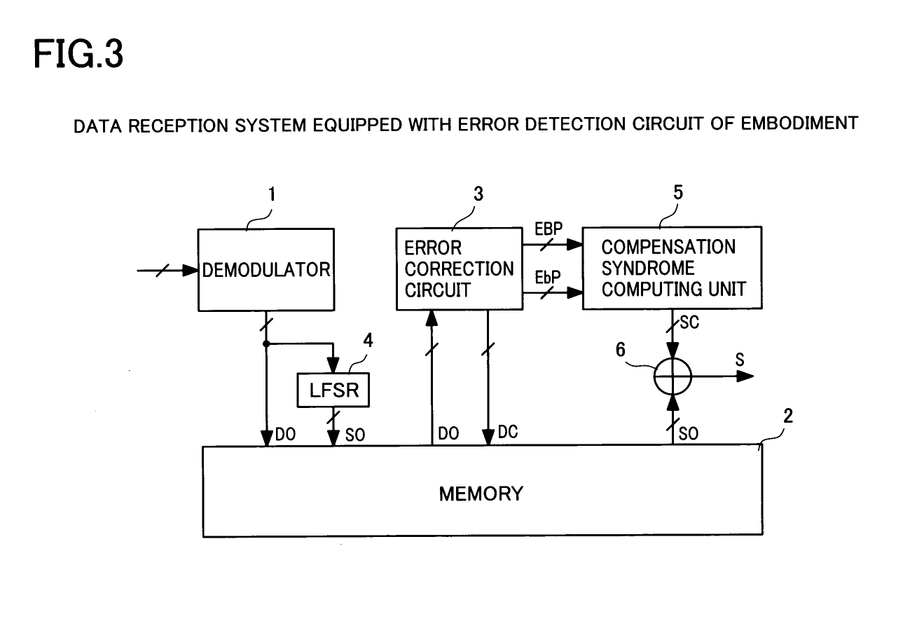

FIG. 3 is an explanatory diagram of a principle of a reception system equipped with an error detection apparatus. Data output from a DVD is received by a demodulator 1 to be converted into received data DO. The converted received data DO is input to an LFSR 4, which computes an initial syndrome SO. Simultaneously, it is stored in a memory 2. Then, the received data DO is read from the memory 2 and goes through an error correction circuit 3 to undergo error correction. The corrected received data DC is stored in the memory 2. Further, the initial syndrome SO computed by the LFSR 4 is also stored in the memory 2.

In a case where an error is corrected by the error correction circuit 3, error byte position information EBP that indicates a byte position where the error exists in the received data DO and error bit position information EbP that indicates an error bit position in an error byte position pinpointed by the error byte position information EBP are directed to a compensation syndrome computing unit 5. In the case of one-sector data of the DVD, the error byte position information EBP has a length of 12 bits in order to identify 2064 bytes. The error bit position information EbP has a length of eight bits in order to identify the bit position in each byte.

The compensation syndrome computing unit 5 performs computations equivalent to those by the LFSR 4 based on the error byte position information EBP and the error bit position information EbP and outputs a compensation syndrome SC. The initial syndrome SO read from the memory 2 and the compensation syndrome SC are EXOR-ed by an adder (EXOR) 6 to output a syndrome S.

It is possible to compute the compensation syndrome SC from the error byte position information EBP and the error bit position information EbP. In this case, it is unnecessary to input the corrected received data DC to the LFSR 4 and shift it for as many times as 16512, which is equal to a total number of bits. The compensation syndrome SC can be computed in a short time. In this case, since the compensation syndrome SC is computed using minimum required data from the error byte position information EBP and the error bit position information EbP, it is possible to configure a control circuit or a data table required in computation so that they may have a small scale circuit configuration.

Further, access to the memory 2 comes in storage of the received data output from the demodulator 1, reading of the received data DO, and storage of the corrected received data DC. When performing error detection on the error-corrected received data DC, it is unnecessary to read the corrected received data DC from the memory 2, thereby enabling reducing the number of times of gaining access to the data in the memory 2.

It is to be noted that the error detection apparatus includes the compensation syndrome computing unit 5 and an adder (EXOR) 6.

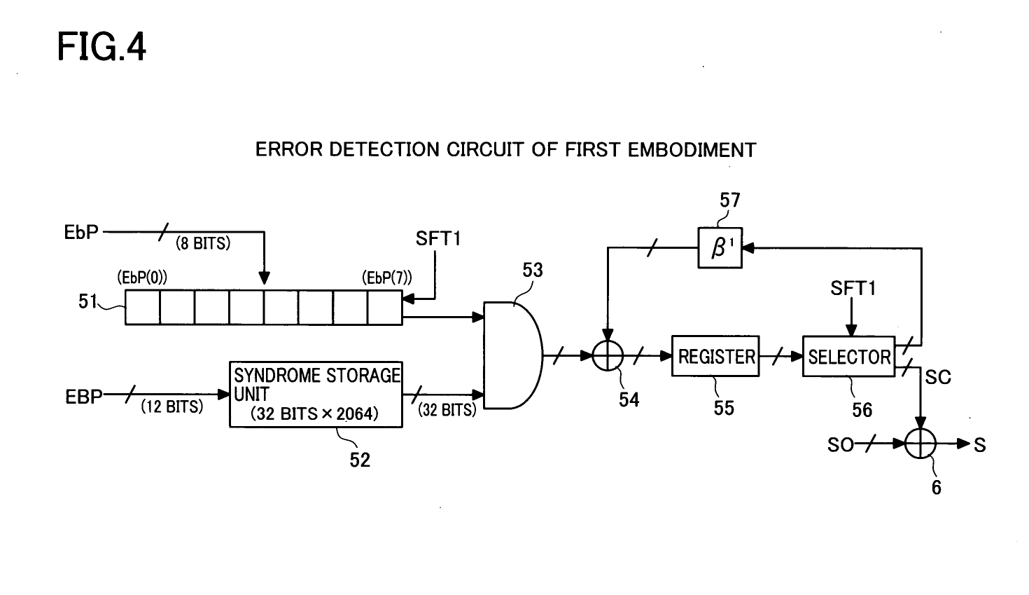

FIGS. 4-7 show an error detection apparatus and an error detection method of a first embodiment. FIG. 4 is a circuit diagram of the error detection apparatus. It includes a register 51 that stores error bit position information EbP, by which data bits of the MSB (EbP(7)) through the LSB (EbP(0)) are sequentially input to an AND gate 53 in accordance with a shift signal SFT1.

It further includes a syndrome storage unit 52, in which such a syndrome is stored beforehand that an error bit exists at a specified bit position in each of bytes (B0-B2063) of received data DO. Each syndrome is constituted of 32 bits of X⁰-X³¹ shown in FIG. 2 which illustrates the LFSR. It is to be noted that since received data is constituted of 2064 bytes, 2064 types of syndromes are stored. In the syndrome storage unit 52, (32×2064) data bits are stored in total.

To the syndrome storage unit 52, error byte position information EBP is input. The error byte position information EBP is 12-bit data that indicates a byte position where an error exists in received data DO. The 12-bit data is used to select one of the 2064 bytes. In response to the input error byte position information EBP, the corresponding syndrome is output from the syndrome storage unit 52 in a condition where it has a 32-bit width. The output syndrome is input to the AND gate 53.

It is to be noted that the following description exemplifies a case where the specified bit position is the LSB (EbP(0)) of each of the bytes.

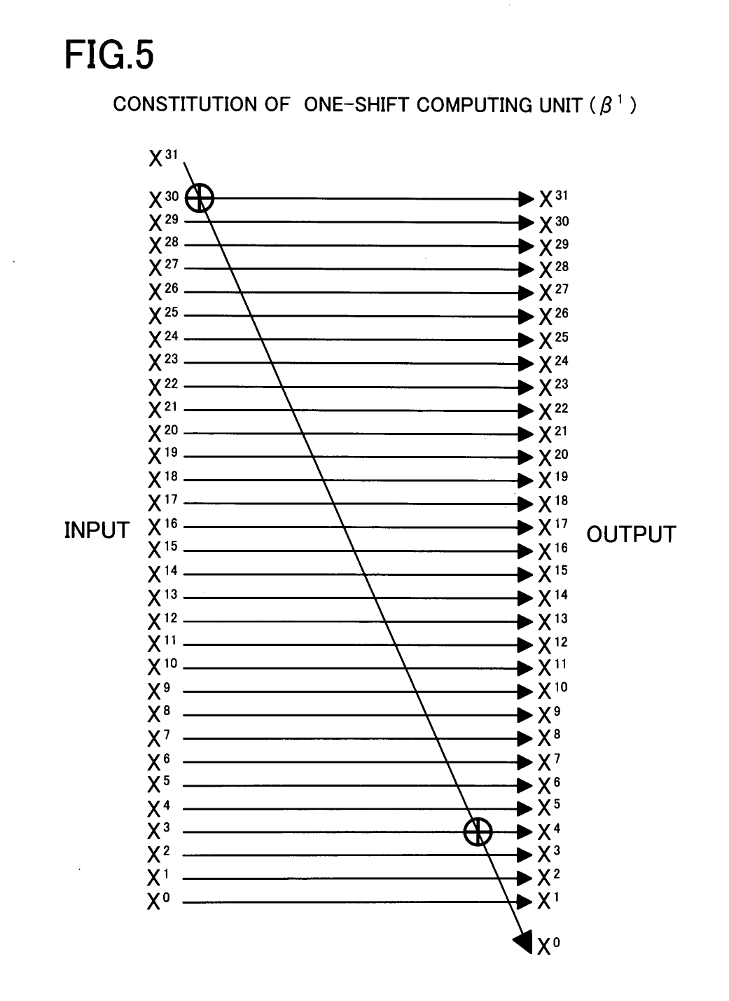

If the bit data output from the register 51 indicates value “1”, which indicates that an error exists, the AND gate 53 outputs a syndrome. The output syndrome is input to an adder (EXOR) 54. The adder (EXOR) 54 is supplied also with bit data having a 32-bit width output from a one-shift computing unit (β¹) 57, which is described later with reference to FIG. 5, a result of adding by which is input to a register 55. The adder (EXOR) 54 performs exclusive OR-operation between the syndrome output from the AND gate 53 and the 32-bit data output from the one-shift computing unit (β¹) 57.

An output from the register 55 is input to a selector 56. The selector 56 is controlled by the shift signal SFT1. The selector 56 connects the register 55 to an input terminal of the one-shift computing unit (β¹) 57 for as many times as the number of bits as counted from an error bit position of the shift signal SFT1 to the LSB (EbP(0)). The number is seven at the maximum. The one-shift computing unit (β¹) 57 sequentially performs computations in accordance with the shift signal SFT1, thus causing a compensation syndrome SC to be stored in the register 55. In response to the next pulse of the shift signal SFT1, the selector 56 is connected to an input terminal of a adder (EXOR) 6. The adder (EXOR) 6 performs exclusive OR-operation between an initial syndrome SO output from an LFSR 4 (FIG. 3) and a compensation syndrome SC. A result of the computations provides a syndrome S of an error-corrected received data DC.

In the error detection circuit of the first embodiment, error bit position information EbP stored in the register 51 is sequentially selected starting with higher-order bits in accordance with the shift signal SFT1. In a case where bit data of a selected bit position is value “1” to indicate that an error exists at the bit position, error byte position information EBP is used to output from the syndrome storage unit 52 to the adder (EXOR) 54 such a syndrome that the error bit position may exist at the LSB (EbP(0)) in a byte position where an error exists in received data DO. The 32-bit data output from the adder (EXOR) 54 is once stored in the register 55 and then goes through the one-shift computing unit (β¹) 57 to undergo computations equivalent to a one-shift operation by the LFSR 4 in response to the shift signal SFT 1, a result of which is sent to the adder (EXOR) 54. If a syndrome is output from the AND gate 53, in the adder (EXOR) 54, the syndrome is EXOR-ed with the 32-bit data output from the one-shift computing unit (β¹) 57 and, otherwise, sends the 32-bit data as it is to the register 55.

FIG. 5 shows computing operations by the one-shift computing unit (β¹) 57. Bit data corresponding to bit position (X³) and bit data corresponding to bit position (X³¹) are EXOR-ed to provide bit data corresponding to bit position (X⁴). Bit data corresponding to bit position (X³⁰) and bit data corresponding to bit position (X³¹) are EXOR-ed to provide bit data corresponding to bit position (X³¹). Bit data pieces corresponding to the other bit positions (X⁰)-(X²) and (X⁴)-(X²⁹) are provided as those corresponding to bit positions (X¹)-(X³) and (X⁵)-(X³⁰), which are each shifted up by one-bit in bit position. The one-shift computing unit (β¹) 57 shown in FIG. 5 indicates that a result of computations equivalent to one-bit shift operations in the LFSR (FIG. 2) can be realized by a combinational logical circuit equipped with an adder (EXOR).

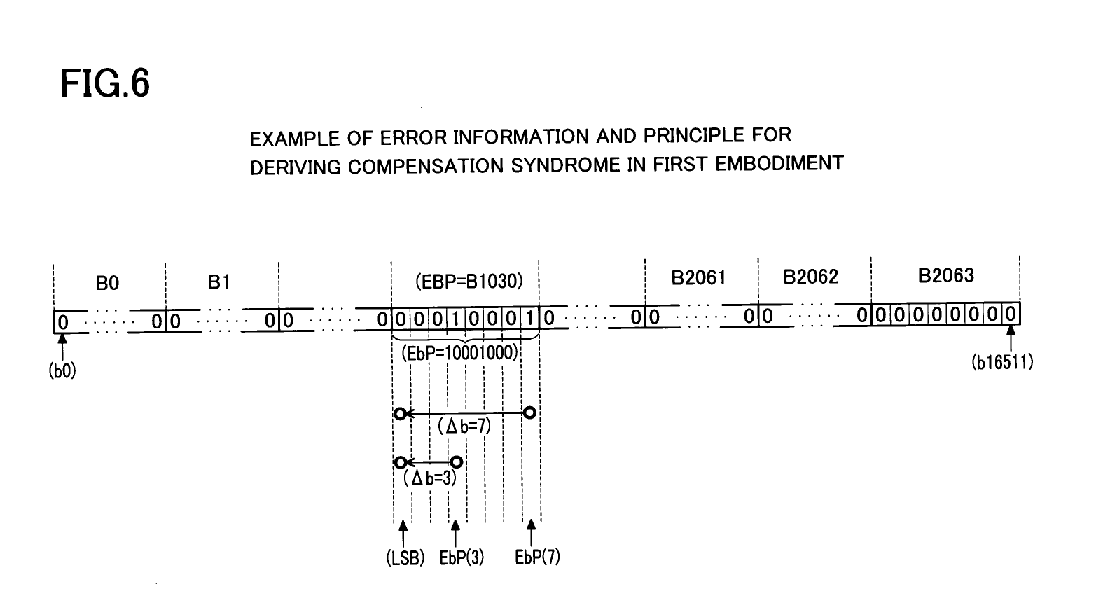

A principle on which a corrected syndrome SO is computed in the first embodiment is described blow with reference to FIG. 6. A bit row shown in FIG. 6 is error correction information at the time when error correction is performed on received data DO by an error correction circuit 3 (FIG. 3). In FIG. 6, it is supposed that error correction is performed on bit data in byte 1030 (B1030) (error byte position information EBP=B1030). It is further supposed that in byte 1030, an error exists at bit 7 (EbP(7)) and bit 3 (EbP(3)) (error bit position information EbP=“10001000”).

In the first embodiment, such a syndrome that an error exists at an error bit position of the LSB (EbP(0)) in each of bytes of received data DO is stored in the syndrome storage unit 52 beforehand. Now, suppose that an error exists at bit 7 (EbP(7)) and the other bit positions in the received data DO are free of errors. This means that bit data of value “0” is stored at the bit positions other than bit 7 (EbP(7)). In this case, a bit difference as counted from bit 7 (EbP(7)) to the LSB (EbP(0)) is Δb=7.

In the LFSR (FIG. 2) that computes a syndrome, received data DO is sequentially input starting with the MSB (b16511), so that in a case where such a syndrome is set that an error exists at the LSB (EbP(0)) in a bit position of bit 7 (EbP(7)), by performing a shift operation that corresponds to Δb=7 on the syndrome, such a syndrome is obtained that an error exists at the bit position of bit 7 (EbP(7)).

This is because, since bit data is set to value “1” only at the one bit of the error bit position and bit data “0” is set to all the other bit positions, by performing a shift operation that corresponds to the bit difference on the syndrome that the error bit position is the LSB (EbP(0)), such a syndrome can be obtained that an error bit position exists on the higher-order bit side of the LSB (EbP(0)).

Similarly, in a case where an error exists at a bit position of bit 3 (EbP(3)) also, the other bit positions are free of errors and have value “0” stored as bit data, so that by performing a shift operation that corresponds to a bit difference (Δb=3) on such a syndrome that an error bit position is the LSB (EbP(0)), a syndrome that an error bit position is bit 3 (EbP(3)) can be obtained.

In error detection by use of a cyclic code, a syndrome can be EXOR-ed for each error bit position, so that by EXOR-ing a computation result obtained by performing a shift operation that corresponds to a bit difference from the LSB (EbP(0)) for each error bit position as described above, a syndrome can be obtained for each of the error bits. The obtained syndrome provides a compensation syndrome SC.

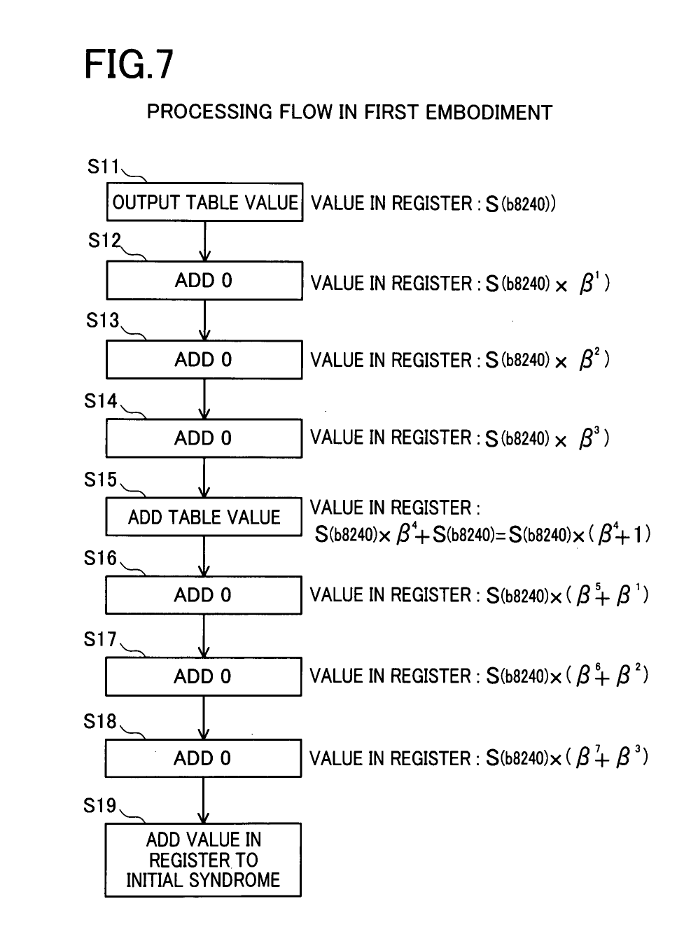

FIG. 7 is a processing flow which shows an error detection method of the first embodiment. The process flow is aimed at the error bit position shown in FIG. 6. In the processing flow of FIG. 7, each time a step moves, computations equivalent to a one-shift operation by the LFSR are performed on 32 data bits (X⁰-X³¹) stored in the register. This processing is expressed as multiplication by β¹. FIG. 7 exemplifies a case where error correction information contains error byte position information EBP=B1030 and error bit position information EbP=“10001000”.

First, the process outputs a syndrome S (b8240) that an error bit exists at the LSB (EbP(0)) in byte 1030 (B1030) as a table value from a table in accordance with the error byte position information EBP=B1030 (S11). The syndrome S (b8240) that corresponds to the error byte position information EBP=B1030 is stored in the register. In this case b8240 is the bit position LSB (EbP(0)) in byte 1030 (B1030).

Next, a value “0” is EXOR-ed as bit data. The number of times of EXOR-ing is three (S12-S14). The EXOR-ed result is stored in the register. The value in the register changes as S(b8240)×β¹, S(b8240)×β², and S(b8240)×β³ in this order as the step goes. During the steps, bit data value “0” is EXOR-ed, so that the computations are equivalent to one-shift operations which are performed sequentially by the LFSR on the value in the register.

At step (S15), the process outputs a syndrome S (b8240) as a table value from the table again, it is EXOR-ed with bit data obtained by performing computations equivalent to the on-shift operation on the bit data stored already in the register, and stores a result in the register. Now, the value in the register is S(b8240)×β⁴+S(b8240)=S(b8240)×(β⁴+1).

Next, a value “0” is EXOR-ed as bit data again. The number of times of EXOR-ing is two (S16-S18). The EXOR-ed result is stored in the register. The value in the register changes as S(b8240)×(β⁵+β¹), S(b8240)×(β⁶+β²), and S(b8240)×(β⁷+β³) in this order. During the steps, bit data value “0” is EXOR-ed, so that computations equivalent to one-shift operations which are performed sequentially by the LFSR are performed on the value in the register. The bit data stored in the register at step (S18) provides a compensation syndrome SC.

By EXOR-ing the compensation syndrome SC given as a value stored in the register with the initial syndrome SO computed before error correction (S19), the syndrome S is computed, thereby enabling performing error detection.

The following will describe the above processing flow as correlating it with processing in an error processing apparatus of FIG. 4. A table at step (S11) corresponds to a table of a syndrome stored in the syndrome storage unit 52. Step (S11) indicates that the MSB (EbP(7)) stored in the register 51 is read, which is an error bit, so that the corresponding syndrome S(b8240) is output from the syndrome storage unit 52 via the AND gate 53.

Steps (S12)-(S14) and (S16)-(S18) correspond to a process that value “0” is output as bit data from the register 51 and value “0” is output from the AND gate 53. During the process, the bit data stored beforehand in the register 55 undergoes, via the selector 56, computations equivalent to a one-shift operation by the one-shift computing unit (β¹) 57 and then is set back to the register 55 via the adder 54.

Step (S15) indicates that bit 3 (EbP(3)) stored in the register 51 is read, which is an error bit, so that the syndrome S(b8240) is output again from the syndrome storage unit 52 via the AND gate 53.

Step (S19) corresponds to the adder (EXOR) 6.

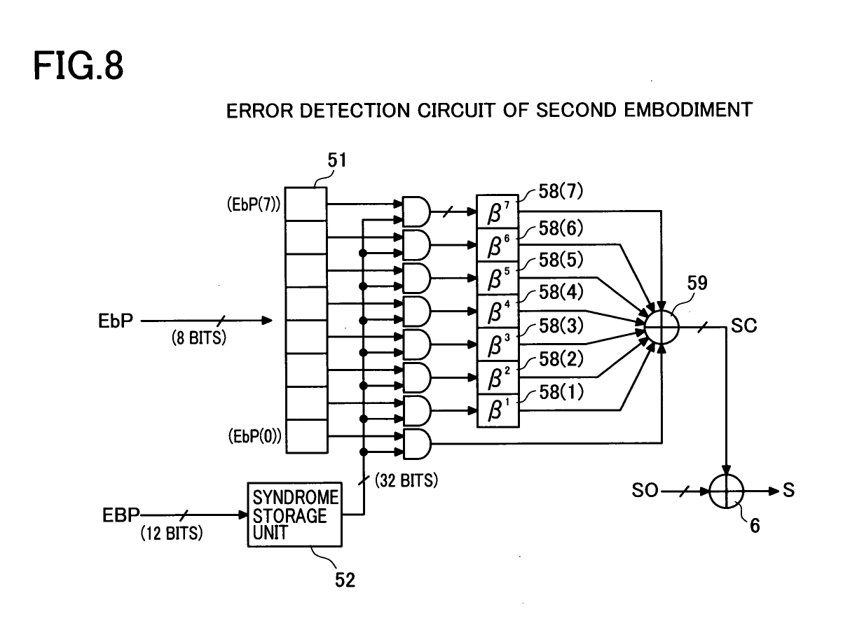

FIG. 8 shows an error detection circuit of a second embodiment. A register 51, a syndrome storage unit 52, and an adder (EXOR) 6 are the same as those of the first embodiment (FIG. 4). In the second embodiment, in place of the AND gate 53 of the first embodiment, an AND gate is provided for bit data at each of bit positions contained in error bit position information EbP stored in the register 51. Each AND gate obtains a logical product of each of bit data pieces in the register 51 and a syndrome output from the syndrome storage unit 52 in accordance with error byte position information EBP and, if value “1” is stored as the bit data being at an error bit position, outputs a syndrome.

The output syndromes other than those which are output from the AND gate connected to the LSB (EbP(0)) of the register 51 are input to shift computing units (β¹) 58(1) through (β⁷) 58(7), which outputs a result of computing equivalent to the shift operation which are performed for as many times as the predetermined at LFSR, respectively. The shift computing units (β¹) 58(1) through (β⁷) 58(7) are provided as shift computing units unique to first through seventh bits (EbP(1) through EbP(7)) of the register 51 respectively. The shift computing units (β¹) 58(1) through (β⁷) 58(7) each perform computations equivalent to shift operations which are performed using as a predetermined number a bit difference as counted from each bit position to the LSB (EbP(0)) of the register 51.

Outputs from the shift computing units (β¹) 58(1) through (β⁷) 58 (7) are input to an adder (EXOR) 59 together with an output of the AND gate that corresponds to the LSB (EbP(0)) of the register 51, where they are exclusive OR-ed. An exclusive OR-ed result output from the adder (EXOR) 59 provides a compensation syndrome SC.

The adder (EXOR) 6 performs exclusive OR-operation between an initial syndrome SO output from the LFSR 4 (FIG. 3) and the compensation syndrome SC. A result of the computations provides a syndrome S of error-corrected received data DC.

If bit data is value “1” and exists at an error bit position in the error bit position information EbP stored in the register 51, the error detection circuit of the second embodiment inputs to (β¹) 58(1) through (β⁷) 58(7) a syndrome that an error bit position is the LSB (EbP(0)) in a byte position at which an error exists and which is pinpointed by error byte position information EBP. The shift computing units (β¹) 58(1) through (β⁷) 58(7) perform computations equivalent to a shift operation which is performed for as many times as a bit difference as counted from the error bit position to the LSB (EbP(0)), results of which computations are EXOR-ed by the adder (EXOR) 59. In addition, in the adder (EXOR) 6 it is EXOR-ed with the initial syndrome SO, thereby enabling obtaining a syndrome S.

Instead of repeating computations equivalent to shift operations which are performed for as many times as a bit difference as counted from an error bit position to the LSB (EbP(0)) on a syndrome output from the syndrome storage unit 52 in the error detection circuit (FIG. 4) of the first embodiment, for a number of times that is controlled by a shift signal SFT1 in a one-shift computing unit (β¹) 57, the error detection circuit of the second embodiment has a configuration that the shift computing units (β¹) 58 (1) through (β⁷) 58(7) are provided for each error bit position to thereby performing concurrent processing of computations equivalent to shift operations which are performed for as many times as a bit difference as counted from the error bit position to the LSB (EbP(0)).

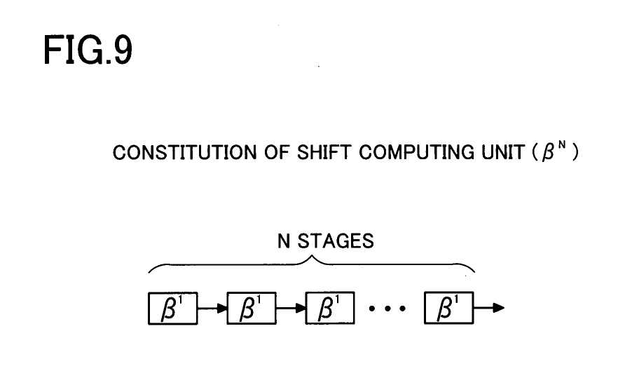

A conceptual diagram of a circuit configuration of the shift computing units (β¹) 58(1) through (β⁷) 58(7) is shown in FIG. 9. By serially connecting N number of stages of the one-shift computing unit described with reference to FIG. 5, it is possible to obtain shift computing units (β¹) 58(1) through (β⁷) 58(7) that output computation results equivalent to a shift operation being performed for N number of times.

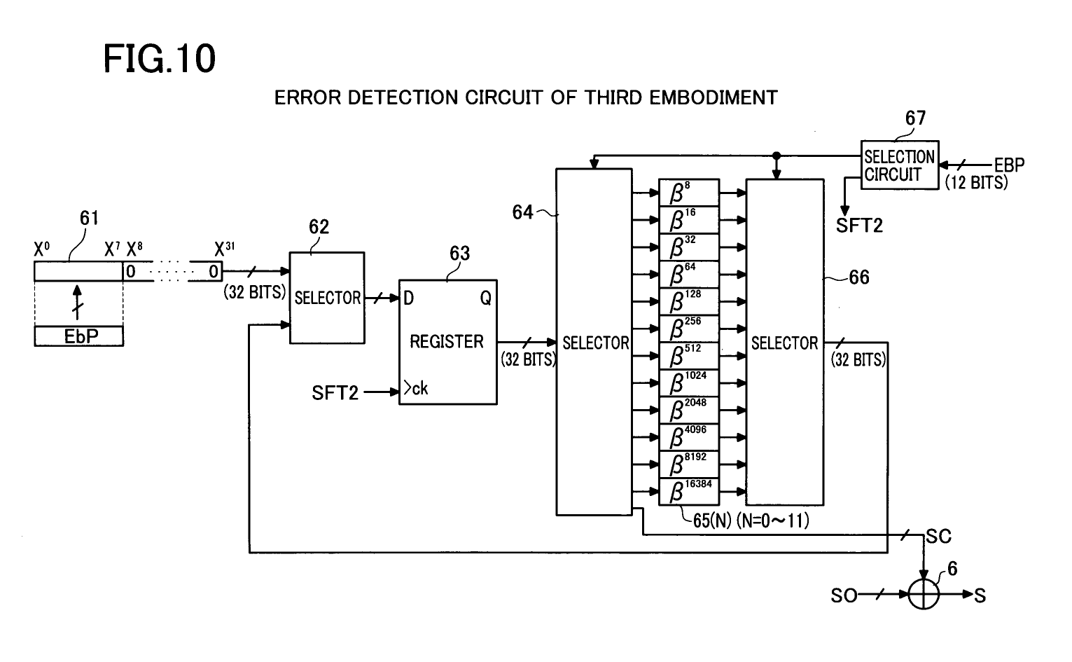

FIGS. 10-12 show an error detection apparatus and an error detection method of a third embodiment. FIG. 10 is a circuit diagram of the error detection apparatus. The apparatus is equipped with a 32-bit long register 61 in which error bit position information EbP is stored in low-order eight bits (X⁰-X⁷). Bit data of value “0” is stored in high-order 24 bits (X⁸-X³¹) of the register 61.

A selector 62 selects either data output from the register 61 or a result of computations equivalent to shift operations by LFSR through a shift computing units 65(N) (N=0-11) (described later) input via a selector 66 and outputs it to a register 63. The register 63 outputs bit data stored in it to a selector 64 in accordance with a shift signal SFT2.

The selector 64 selects any one the shift computing units 65(N) (N=0-11) and an adder (EXOR) 6, to send bit data stored in the register 63. The selector 66 selects any one of the shift computing units 65(N) (N=0-11) and sends a result of computations by the selected shift computing unit 65(N) to the selector 62. The selectors 64 and 66 are controlled by a selection circuit 67. The selection circuit 67 outputs a shift signal SFT2 simultaneously. The selection circuit 67 is supplied with error byte position information EBP, to provide the shift signal SFT2 and signals that select the selector 64 and 66 in accordance with an error byte position. The adder (EXOR) 6 is the same as that shown in FIG. 3.

In an error detection circuit of the third embodiment, first the selector 62 selects the register 61, to initialize the register 63 with contents of the register 61. Then, the selection circuit 67 outputs data stored in the register 63 in accordance with the shift signal SFT2, so that computations are performed by the shift computing unit 65(N) selected by the selectors 64 and 66, a result of which computations is stored into the register 63 via the selector 66. A combination of the shift computing units 65(N) required in computation of a compensation syndrome SC is to be selected by the selection circuit 67, so that the selection circuit 67 causes the selectors 64 and 66 to sequentially select the target shift computing units 65(N) and sequentially store the computation results into the register 63 via the selectors 66 and 62. When the shift computing units 65(N) to be selected on the basis of the error byte position information EBP are all selected, the bit data stored in the register 63 provides the compensation syndrome SC. Then, the selector 64 connects the register 63 to the adder (EXOR) 6. In the adder (EXOR) 6, the compensation syndrome SC is EXOR-ed with the initial syndrome SO, to provide a syndrome S.

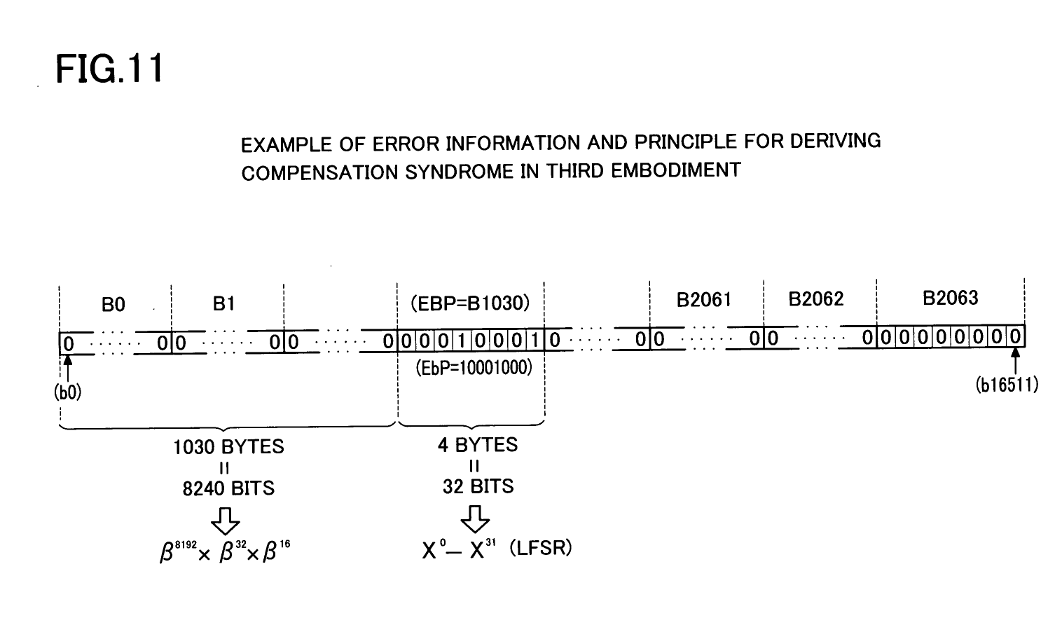

A principle on which a compensation syndrome SC is computed in the third embodiment is described below with reference to FIG. 11. A bit row shown in FIG. 11 is the same as that shown in FIG. 6. As shown in FIG. 4, bit data is input into the LFSR starting with higher-order bits of received data DO in a descending order. Since no error bit exists at higher-order byte positions (B1031-B2063) (higher in order) than byte 1030 (B1030) where an error bit exists, at a moment when the bit data of byte 2063 (B2063) through byte 1031 (B1031) is input into the LFSR, the bit data pieces of bit rows (X⁰-X³¹) that constitute the LFSR are all kept to value “0”.

Then, the LFSR is supplied with byte 1030 (B1030) and further with byte 1029 (B1029) through byte 0 (B0), to compute a syndrome. In the third embodiment, computations are performed which are equivalent to shift operations being performed by the LFSR when byte 1030 (B1030) is input and, further, byte 1029 (B1029) through byte 0 (B0) are input.

First, consider a state where byte 1030 (B1030) is input into the LFSR. Since bit data pieces of bit rows (X⁰-X³¹) in the LFSR all have been of value “0” previously, error bit position information EbP (“10001000”) of byte 1030 (B1030) is stored in low-order eight bits (X⁰-X⁷) of the LFSR. In this case, “0” is already stored in high-order 24 bits rows (X⁸-X³¹) of the LFSR. This state is stored in the register 61.

Next, byte 1029 through byte 0 (B1029-B0) which are lower in order than byte 1030 (B1030) are input. Since bit positions of these bytes are free of errors, bit data takes on value “0”. Accordingly, value “0” is input into the LFSR, so that as shown in FIG. 2, bit data of bit position (X³¹) is input as it is to bit position (X⁰). Therefore, it is only necessary to perform computations equivalent to shift operation of 8240 (=8×1030) bits, which constitute bytes 1029-0 (B1029-B0). This is how the selection circuit 67 controls the selectors 64 and 66. This control selects the shift computing Units (β⁸¹⁹²) 65(10), (β³²) 65(2), and (β¹⁶) 65(1). By performing computations as sequentially selecting these shift computing units, a result of computation can be obtained which are equivalent to a shift operation being performed for as many times as 8192+32+16=8240. The computation is expressed as β⁸¹⁹²×β³²×β¹⁶.

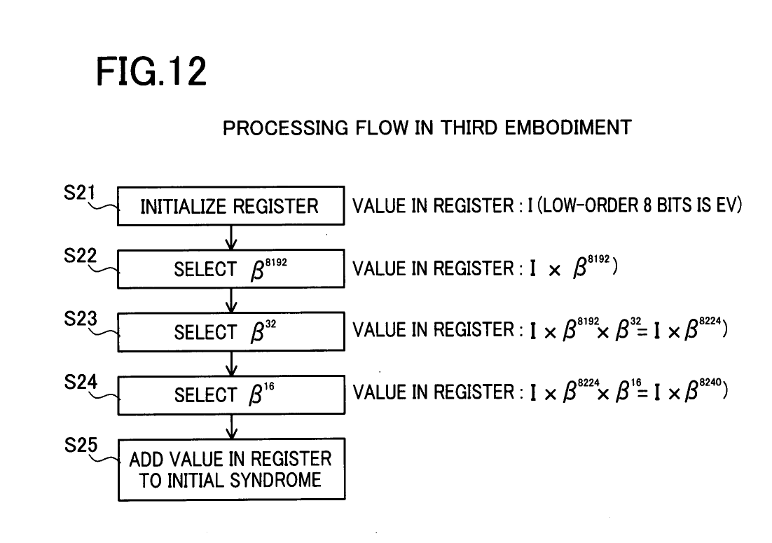

FIG. 12 is a flowchart showing an error detection method of the third embodiment. The processing flow is aimed at the error bit position shown in FIG. 11. FIG. 12 has exemplified a case where error correction information contains error byte position information EBP=B1030 and error bit position information EbP=“10001000”.

First, the process provides the register with the error bit position information EbP=“10001000” as low-order eight bits and initializes bit data pieces of high-order 24 bits with value “0” (S21). Accordingly, a value of the register is initialized with initial value I with low-order eight bits being equal to the error bit position information EbP.

Next, the process performs computations (β⁸¹⁹²) equivalent to shift operations being performed by the LFSR as many times as 8192 (S22). Subsequently, the process performs computations (β³²) equivalent to 32 times of shift operations (S23). Further, the process performs computations (β¹⁶) equivalent to 16 times of shift operations (S24). Accordingly, the register takes on a value of I×β⁸¹⁹², I×β⁸¹⁹²×β³²=I×β⁸²²⁴, and I×β⁸²²⁴×β¹⁶=I×β⁸²⁴⁰. The thus obtained register value (I×β⁸²⁴⁰) provides a compensation syndrome SC.

By EXOR-ing the compensation syndrome SC, which is a register value, with the initial syndrome SO computed before error correction (S25), a syndrome S can be computed to detect an error.

The following will describe the above processing flow as correlating it with processing in the error processing apparatus of FIG. 10. The register at step (S21) corresponds to the register 61. The register 61, which is 32-bit long, is set to a state where bit data of byte 1030 (B1030) having an error is input in the bit rows (X⁰-X³¹) of the LFSR. By using this state as an initial value, a shift operation is performed for a predetermined number of times in low-order cycles.

Processing of step (S22) through step (S24) corresponds to processing of bit data output from the register 63 being input into the shift computing units (β⁸¹⁹², β³², β¹⁶) 65(10), 65(2), and 65(1) which is sequentially selected by the selector 64 and returned to the register 63 via the selector 66.

Step (S25) corresponds to the adder (EXOR) 6.

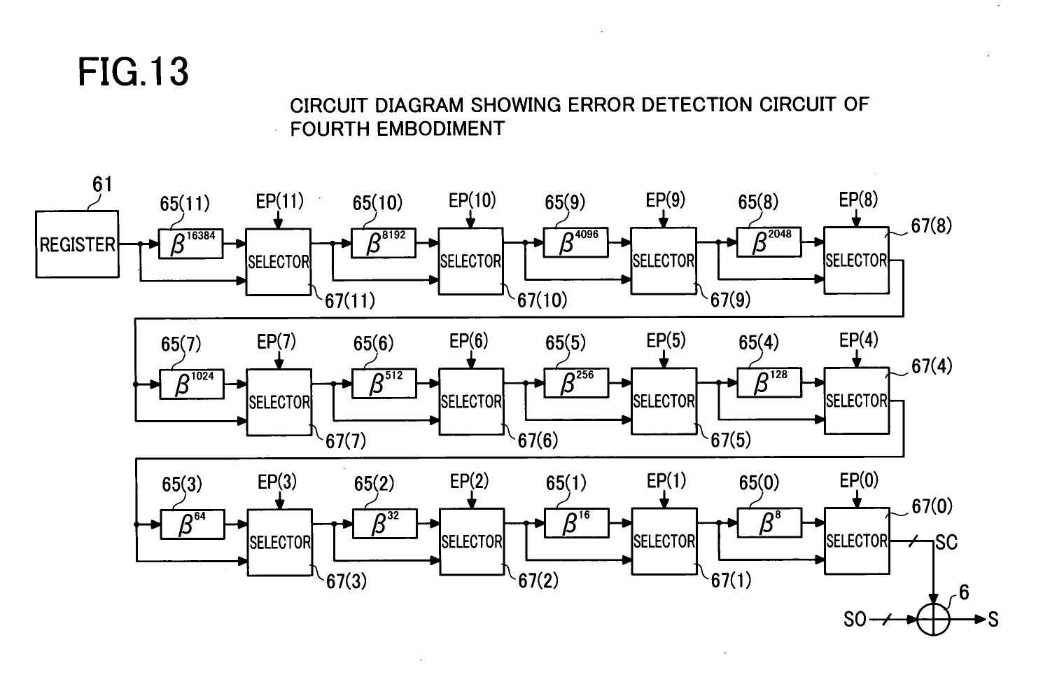

FIG. 13 shows an error detection circuit of a fourth embodiment. A register 61, a shift computing unit 65(N), and an adder (EXOR) 6 are the same as those of the third embodiment (FIG. 10). Instead of sequentially selecting the shift computing units 65 (N) in the third embodiment, the fourth embodiment simultaneously selects the required shift computing units 65 (N).

The shift computing units 65(11) through 65(0) are equipped with selectors 67(11) through 67(0), respectively. The selectors 67(11) through (0) are controlled respectively by bit data pieces EBP(11) through EBP(0) of error byte position information EBP. For initial data which is output from the register 61, the shift computing units 65(N) are selected and connected in series, to perform computations so as to be equivalent to further required shift operations being performed by an LFSR, thereby working out a compensation syndrome SC.

As described in detail above, according to the error detecting apparatus and the error detection method according to the first and second embodiments, by performing computations equivalent to a shift operation being performed by the LFSR for as many times as a bit difference as counted from an error bit position in the byte position having the error to LSB (EbP(0)), on a syndrome which is computed if an error exists at the LSB (EbP(0)) in a byte position having an error in received data and EXOR-ing results of the computations for each of the error bit positions, it is possible to obtain a compensation syndrome SC, which is a compensation value for an initial syndrome SO. It is unnecessary to obtain the compensation syndrome SC by performing a shift operation by the LFSR for as many times as a total number of bits of the received data DO based on the error byte position information EBP and the error bit position information EbP, thereby enabling compensating the initial syndrome SO in a short computation time.

Further, the stored syndrome is such as that an error exists at the LSB (EbP(0)) in each of the bytes that constitute the received data DO, so that only one syndrome is stored for each byte position. As compared to the case of storing a syndrome that an error exists at each of all of the bits in all of the bytes of the received data DO, an amount of data to be stored can be reduced. A storage region can be limited to a small area, thereby reducing a scale of a circuitry including also a control circuit for the storage region.

Further, according to the error detection apparatus and the error detection method of the first embodiment, bit data pieces of the error bit position information EbP are sequentially taken out starting with higher-order bits thereof and a syndrome is taken out from a syndrome storage unit 52 for each of bit positions that taken out, to then perform shift operations sequentially for as many times as a bit difference as counted up to the LSB (EbP(0)). If a plurality of the bit positions have errors, it is possible to sequentially perform computations equivalent to the shift operations as sequentially EXOR-ing results of computations by using an adder (EXOR) 54. As a computing unit to perform computations equivalent to the shift operations, it is only necessary to equip a one-shift computing unit (β¹) 57, thereby enabling performing computations with a small scale circuit constitution.

Further, according to the error detection apparatus and the error detection method of the second embodiment, in a case where errors exist at a plurality of bit positions in the error bit position information EbP, it is possible to perform computations on the error bit positions concurrently. It is thus possible to shorten a computation time.

It is to be noted that each byte in the received data DO is one example of the data unit and, in this case, a predetermined number of bits is eight. Further, the LSB (EbP(0)) in byte is one example of the specified bit position. Further, the initial syndrome SO, the compensation syndrome SC, and the compensated syndrome S are one example of the first, second, and third syndromes, respectively. Further, the error byte position information EBP and the error bit position information EbP are each one example of constitute error correction information, and the LFSR 4 is one example of the first linear feedback shift register.

Further, in the first and second embodiments, the syndrome storage unit 52 is one example of the storage unit. Further, the AND gate 53, the register 55, the selector 56, and the one-shift computing unit (β¹) 57 in the first embodiment and the AND gate and the shift computing units (β¹) 58(1) through (β⁷) 58(7) in the second embodiment are each one example of the computing unit. Further, the adders (EXOR) 54 and 59 are one example of a first adder and the adder (EXOR) 6 is one example of a second adder.

Further, in the first embodiment, the register 55 is one example of the register unit, the one-shift computing unit (β¹) 57 is one example of the one-shift computing unit, and the register 51 is one example of the bit selection unit. On the other hand, in the second embodiment, the shift computing units (β¹) 58 (1) through (β⁷) 58 (7) are one example of a plurality of first shift computing units and a first individual shift computing unit and the register 51 and the AND gate are one example of a first selection unit.

Further, according to the error detection apparatus and the error detection method of the third and fourth embodiments, by allocating a bit row of error bit position information EbP of a byte position having an error as low-order eight bits of a 32-bit bit row (X⁰-X³¹) of the LFSR to thereby provide an initial code and combining computations equivalent to a shift operation being performed by the LFSR for as many as up to a number of bit that is obtained by subtracting eight bits of each byte from 16512 bits, which is a total number of bits, it is possible to obtain a result of computations equivalent to shift operations which are performed for as many times as the number of bits lower in order than a byte position pinpointed by the error byte position information EBP, thereby acquiring a compensation syndrome SC. It is unnecessary to obtain the compensation syndrome SC by using the LFSR after performing a shift operation for as many times as the total number of bits of the received data DO based on the error bit position information EbP and the error byte position information EBP, thereby enabling compensating the initial syndrome SO in a short computation time.

In this case, it is unnecessary to store beforehand such a syndrome that an error exists at the LSB (EbP(0)) of each byte. The storage region and the control circuit for the region are unnecessary, thus enabling reducing the scale of the circuitry.

Further, according to the error detection apparatus and the error detection method of the third embodiment, the error bit position information EbP is allocated as low-order eight bits of the 32-bit bit row (X⁰-X³¹) of the LFSR to thereby provide an initial code. On the initial code, it is necessary to perform, by using the LFSR, a shift operation for as many times as the number of bits included in byte positions which are lower in order than a byte position pinpointed by the error byte position information EBP. Computations equivalent to the shift operations can be sequentially selected and performed by the shift computing unit 65 (N) (N=0-11) based on the error byte position information EBP. In this case, since the error bit position information EbP is taken in as an initial code, a compensation syndrome SC can be computed by the same computations regardless of the number of the bit positions where an error exists. The computations can be performed with a small scaled circuit constitution.

Further, according to the error detection apparatus and the error detection method of the fourth embodiment, computations equivalent to shift operations which are further required as against the error bit position information EbP are selected by the selectors 65 (N) simultaneously and the required shift computing units 65 (N) are connected in series. The shift computing units 65 (N) need not be selected sequentially, thus enabling performing computations by conducting simple control.

It is to be noted that in the third and fourth embodiments, the shift computing units 65 (N) (N=0-11) are each one example of the plurality of second shift computing units and one example of the second individual shift computing unit. The selectors 64 and 66 in the third embodiment and the selector 67 (N) (N=0-11) in the fourth embodiment are one example of the second selection unit. Further, the register 61 is one example of an initial setting unit.

Further, in the third embodiment, the selector 62 is one example of a third selection unit and the register 63 is one example of the register unit. Further, the adder (EXOR) 6 is one example of the second adder.

The present invention is not restricted to the above-described embodiments but needless to say, may be improved or modified in various ways within a scope not departing from the present invention.

For example, when computing a compensation syndrome SC in the present embodiment, the linear feedback shift register (LFSR) (FIG. 2) can also be used.

Although in the first embodiment, means has been described which repeatedly inputs bit data into the one-shift computing unit (β¹) 57 to obtain a result of computations equivalent to a shift operation being performed for a predetermined number of times, the present invention is not limited to it; such a configuration can be employed that a plurality of shift computing units may be equipped which can obtain a result of computations equivalent to different or the same shift operations.

On the contrary, such a configuration can be employed that in the second embodiment the shift computing units 58 (1)-58(7) may be replaced by the one-shift computing unit (β¹), to repeat the computation for the predetermined number of times.

In the third and fourth embodiments, similarly, the configuration of the shift computing units 65(N) may be modified as in the cases of the first and second embodiments.

By the present embodiment, when detecting an error by using a cyclic code, it is possible to efficiently compute a compensation value of a syndrome based on error correction information obtained by error correction processing, thereby shortening a processing time required in compensation and simplifying a circuitry required in compensation processing.

What is claimed is:

1. An error detection apparatus comprising:
a first linear feedback shift register creating a first syndrome by using a cyclic code before error correction for received data in which a plurality of data units are arrayed each of which is constituted of a bit row constituted of a predetermined number of bits;
a storage unit storing beforehand, for each of the data units, a second syndrome which is computed in a case where an error exists at a specified bit position in the bit row;
a computing unit reading from the storage unit, as an initial code, the second syndrome in the data unit that is pinpointed by the error correction information as containing the error and outputs a result of computations equivalent to a shift operation being performed by a linear feedback shift register as many times as a bit difference as counted from an error bit position to the specified bit position in the data unit;
a first adder unit that the computation results output from the computing unit for each of the error bit positions is EXOR-ed with and to be output as a third syndrome; and
a second adder unit that the first syndrome is EXOR-ed with the third syndrome.

2. The error detection apparatus according to claim 1, wherein the computing unit is equipped with a second linear feedback shift register that performs syndrome computations.

3. The error detection apparatus according to claim 1, wherein the computing unit comprises:
a plurality of first shift computing units outputting results of computations equivalent to a shift operation being performed for different numbers of times, the numbers each being up to a bit difference as counted from an MSB to an LSB of the bit row in the data unit; and
a first selection unit selecting at least one of the plurality of first shift computing units in accordance with the bit difference as counted from the error bit position to the specified bit position.

4. The error detection apparatus according to claim 3, wherein the plurality of first shift computing units selected by the first selection unit are coupled in series.

5. The error detection apparatus according to claim 3, wherein:
the plurality of first shift computing units are equipped with a first individual shift computing unit that outputs a result of computations equivalent to the shift operation, which is performed as many times as the bit difference as counted from each of the bit positions to the specified bit position, at each of the bit positions from the MSB to a bit position that is one bit higher in order than the specified bit position of the bit row in the data unit;
the first selection unit inputs the second syndrome to the first individual shift computing unit that corresponds to the error bit position; and
the first adder unit performed EXOR-operation the computation results output from the first individual shift computing unit.

6. The error detection apparatus according to claim 1, wherein the computing unit comprises:
a register unit initialized to the second syndrome; and
a one-shift computing unit outputting the result of computations equivalent to the shift operation of one bit for the code held in the register unit and returns it to the register unit, to repeat processing in the one-shift computing unit as many times as the bit difference.

7. The error detection apparatus according to claim 6, comprising a bit selection unit sequentially selecting, in bit units, the bit row of the data unit pinpointed by the error correction information starting from the MSB, wherein:
in a case where the bit position selected by the bit selection unit is an error bit position, the second syndrome of the data unit pinpointed by the error correction information is EXOR-ed by the first adder unit with the computation result output from the one-shift computing unit; and
each time the bit selection unit performs selection, contents of the register unit are updated with the computation result output from the one-shift computing unit or a result of adding (EXOR) by the first adder unit.

8. An error detection apparatus that compensates a syndrome based on error correction information of the received data rewritten by the error correction, the error detection apparatus comprising:
a first linear feedback shift register creating a first syndrome by using a cyclic code before error correction for received data in which a plurality of data units are arrayed each of which is constituted of a bit row constituted of a predetermined number of bits,
a plurality of second shift computing units outputting results of computations equivalent to a shift operation being performed for different number of times by a linear feedback shift register, the numbers each being up to a number of bits obtained by subtracting the predetermined number of bits constituting the data unit from a total number of bits constituting the received data;
a second selection unit selecting at least one of the plurality of second shift computing units in order to acquire a result of computations equivalent to the shift operation being performed for as many times as the number of bits that are lower in order than the data unit in the received data pinpointed by the error correction information as having an error; and
an initial setting unit allocating a bit row indicating an error bit position in the data unit pinpointed by the error correction information to a low-order bit of the bit rows constituting a linear feedback shift register, as an initial code for the plurality of second shift computing units selected by the selection unit.

9. The error detection apparatus according to claim 8, wherein the plurality of second shift computing units comprise a second individual shift computing unit outputting a result of computations equivalent to the shift operation being performed for as many times as a number obtained by multiplying the predetermined number of bits by a power of two.

10. The error detection apparatus according to claim 8, wherein the plurality of second computing units selected by the second selection unit are coupled in series.

11. The error detection apparatus according to claim 8, wherein the second selection unit sequentially selects the plurality of second shift computing units.

12. The error detection apparatus according to claim 11, comprising:
a third selection unit selecting the initial setting unit first and then selects any one of the plurality of second shift computing units selected by the second selection unit; and
a register unit storing a code output from the third selection unit and outputting it to any one of the plurality of second shift computing units selected next by the second selection unit.

13. The error detection apparatus according to claim 1, wherein the specified bit position is an LSB of the bit row in the data unit.

14. The error detection apparatus according to claim 8, wherein the specified bit position is an LSB of the bit row in the data unit.

15. An error detection method for compensating a syndrome based on error correction information of the received data rewritten by the error correction, the error detection method comprising:
creating a first syndrome by using a cyclic code before error correction for received data in which a plurality of data units are arrayed each of which is constituted of a bit row constituted of a predetermined number of bits, storing beforehand, for each of the data units, a second syndrome which is computed in a case where an error exists at a specified bit position in the bit row;
reading the second syndrome in the data unit pinpointed by the error correction information as containing the error;
outputting a result of computations equivalent to a shift operation being performed by a linear feedback shift register for as many times as a bit difference as counted from an error bit position to the specified bit position in the data unit, by using the read second syndrome as an initial code;
EXOR-ing the computation result output for each of the error bit positions and outputting it as a third syndrome; and
EXOR-ing the first syndrome with the third syndrome.

16. The error detection method according to claim 15, wherein the outputting the computation result comprises:
a plurality of first steps of outputting results of computations equivalent to a shift operation being performed for different numbers of times, the numbers each being up to a bit difference as counted from an MSB to an LSB of the bit row in the data unit; and
selecting at least one of the plurality of first steps in accordance with the bit difference as counted from the error bit position to the specified bit position.

17. The error detection method according to claim 15, wherein:
the outputting the computation result comprises:
initializing the second syndrome as an initial code;
outputting a result of computations equivalent to the shift operation for one bit; and
outputting a result of computations equivalent to the shift operation for the one bit is repeated for as many times as the bit difference.

18. An error detection method compensating a syndrome based on error correction information of the received data rewritten by the error correction, the error detection method comprising:
creating a first syndrome by using a cyclic code before error correction for received data in which a plurality of data units are arrayed each of which is constituted of a bit row constituted of a predetermined number of bits,
a plurality of second steps of outputting results of computations equivalent to a shift operation being performed for different number of times by a linear feedback shift register, the numbers each being up to a number of bits obtained by subtracting the predetermined number of bits that constitute the data unit from a total number of bits constituting the received data;
selecting at least one of the plurality of second steps in order to acquire a result of computations equivalent to the shift operation being performed for as many times as the number of bits that are lower in order than the data unit in the received data pinpointed by the error correction information as having an error; and
a step of allocating a bit row indicating an error bit position in the data unit pinpointed by the error correction information to a low-order bit of the bit rows that constitute a linear feedback shift register, as an initial code for the plurality of second steps.

19. The error detection method according to claim 18, wherein each of the plurality of second steps outputs a result of computations equivalent to the shift operation being performed for as many times as a number obtained by multiplying the predetermined number of bits by a power of two.

20. The error detection method according to claim 18, wherein the step of selection sequentially selects the plurality of second steps.
